(19) United States
(12) Patent Application Publication
(10) Pub. No.: US 2006/0275608 A1
(43) Pub. Date: Dec. 7, 2006

(54) B-stageable film, electronic device, and associated process

(75) Inventors: Sandeep Shrikant Tonapi, Niskayuna, NY (US); John Robert Campbell, Clifton Park, NY (US); Ryan Christopher Mills, Rexford, NY (US); Jian Zhang, Schenectady, NY (US); Stephen Andrew Latham, Clifton Park, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/147,061

(22) Filed: Jun. 7, 2005

(51) Int. Cl. B32B 27/38; C08L 63/00; H01L 21/00

(52) U.S. Cl. 428/413; 523/457

(57) ABSTRACT

A B-stageable film that includes a thermal interface material is provided. The film may secure a heat-generating device to a heat-dissipating component, may further cross-link, and may conduct thermal energy from the heat-generating device to the heat-dissipating component. A method of making and using the film is provided, as well as a device that incorporates the film.

### STATEMENT REGARDING FEDERALLY SPONSORED RESEARCH & DEVELOPMENT

This invention was made with Government support under contract number 70NANB2H3034 awarded by National Institute of Standards and Technology. The Government has certain rights in the invention.

### BACKGROUND

The invention includes embodiments that may relate to a heat transfer film. Embodiments may relate to device that includes the heat transfer film. Embodiments may relate to a method of making and/or using the film

A heat-generating device may be attached to a heat-dissipating component that may remove the heat generated by the device during use. Thermal interface material may facilitate heat removal by acting as a thermal conduit between the heat-generating device and the heat-dissipating component.

Thermal interface materials have been developed into forms that may include grease, tape, pad, and adhesive. These different forms of thermal interface materials may have differing thermal properties, compositions, and applications.

Thermal greases may include silicone oils loaded with thermally conductive filler. Because thermal greases may require manual application, the thickness of thermal grease may be difficult to control. Thermal grease may dry out, separate over time, and may be pumped away from an interface layer in response to thermal load cycles.

Thermal tapes and thermal pads may include silicone with thermally conductive filler. The assembly of a heat-dissipating component to a heat-generating device using a thermal tape or a thermal pad may involve manual removal of one or more protective films from the tape or the pad to expose an adhesive layer. A clamping mechanism (e.g., a clip) may be necessary to secure the heat-dissipating component to the heat-generating device when using a tape or a pad as a thermal interface layer. Ease of assembly of the components may be adversely affected by the presence of the protective film(s), the need for a clamping mechanism, and/or the need for registry or alignment of the tape or the pad.

It may be desirable to have a composition with properties that differ from the properties of available compositions. It may be desirable to have a structure with properties that differ from the properties of available structures. It may be desirable to have a device with properties that differ from the properties of available devices.

### BRIEF DESCRIPTION

The invention includes embodiments that relate to a film that includes a thermal interface material. The film may be B-stageable may secure a heat-generating device to a heat-dissipating component, may flow, may further cross-link, and may conduct thermal energy from the heat-generating device to the heat-dissipating component. In one embodiment, a B-staged film may be one or more of solid, tack-free, or hard.

The invention includes embodiments that relate to a B-staged film that includes a thermal interface material. The film may secure a heat-generating device to a heat-dissipating component, may further cross-link, and may conduct thermal energy from the heat-generating device to the heat-dissipating component.

The invention includes embodiments that relate to an electronic assembly. The assembly may include a heat-generating device, a heat-dissipating component, and a film securing the heat-dissipating component to the heat-generating device. The film may include a thermal interface material, may further cross-link, and may conduct thermal energy from the heat-generating device to the heat-dissipating component.

The invention includes embodiments that relate to a method of making an electronic device. The method may include forming a B-staged film on a heat transfer surface of one of a heat-generating device or a heat-dissipating device. The formed B-staged film may have an inward-facing surface in contact with at least a portion of one of the heat transfer surfaces. And, the film may have an outward-facing surface that is initially exposed. The film may secure the heat-generating device to the heat-dissipating component to form a sandwich, the film may further cross-link, and may conduct thermal energy. The exposed film surface may be contacted to the heat transfer surface of the other of the heat-generating device or the heat-dissipating device. The B-staged film may be cured.

### BRIEF DESCRIPTION OF DRAWINGS

FIG. 1 is a schematic diagram of an embodiment including a screen print assembly.

FIG. 2 is a schematic diagram of an embodiment including a side-capillary assembly.

FIG. 3 is a schematic diagram of an embodiment including a central-well assembly.

FIG. 4 is a bar graph depicting thermal resistances at differing pressure loads during cure.

FIG. 5 is a graph that depicting thermal resistance versus bond-line-thickness (BLT).

FIG. 6 is a photograph taken by scanning acoustic microscopy (CSAM).

FIG. 7 is a bar graph depicting percent void at differing pressure loads during cure.

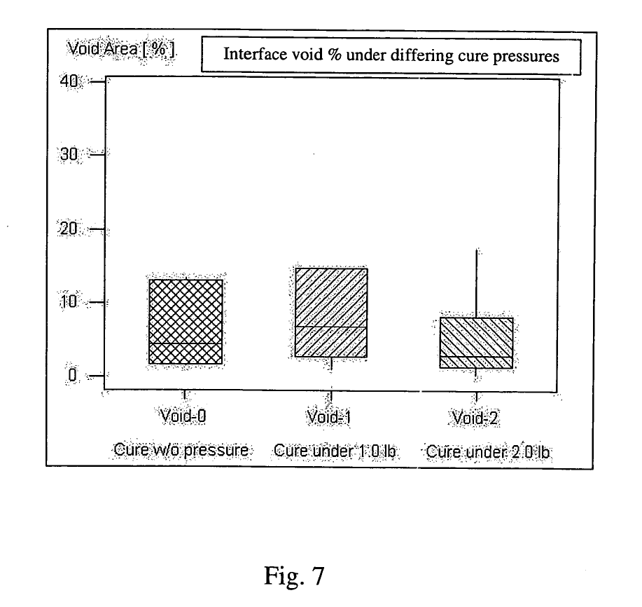

FIG. 8 is a graph depicting thermal resistance versus percent void area.

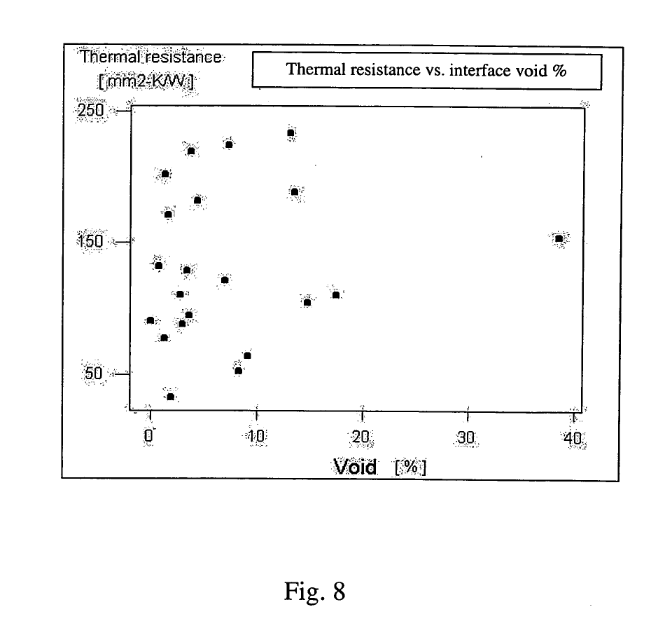

### DETAILED DESCRIPTION

The invention includes embodiments that may relate to a B-stageable film that is thermally conductive, is securable to a heat transfer surface, and is cross-linkable.

A B-staged film may be one or more of solid, tack-free, or hard so that a heat transfer surface, having a B-staged film adhered thereto, may be, for example, stored, shipped, stacked, or otherwise handled, and later assembled to an electronic device. Tack free may refer to a surface that does not possess pressure sensitive adhesive properties at about room temperature. By one measure, a tack free surface will not adhere or stick to a finger placed lightly in contact therewith at about 25 degrees Celsius. Solid refers to a property that a material does flow perceptibly under moderate stress, or has a definite capacity for resisting one or more forces (e.g., compression or tension) that may otherwise tend to deform it. In one aspect, under ordinary conditions a solid may retain a definite size and shape. Thermally conductive may include the ability to conduct heat, and may refer to a physical constant for a quantity of heat that may pass through a predetermined volume in unit of time for units involving a difference in temperature across the volume.

In other aspects, embodiments may relate to one or more of a device having a component or sub-component that is operable to generate heat, to move or remove generated heat, and/or to dissipate heat to a heat sink. Embodiments may relate to a structure or a system for moving or removing thermal energy or heat. Embodiments may relate to a method of making and/or of using the device, a subcomponent of the device, a heat moving or removing structure, or a heat management system.

The term polymer may include a product of polymerization; the polymerization product may include all chemical reaction products comprising one or more repeated units derived from a reactive substrate that is lower in molecular weight than the reaction product. Examples of polymerization products may include one or more of homopolymers, heteropolmers, copolymers, interpolymers, terpolymers, block copolymers, graft copolymers, alternating copolymers, addition polymers, and the like. Alkyl may include normal alkyl, branched alkyl, aralkyl, and cycloalkyl radicals. Normal and branched alkyl radicals may be those containing carbon atoms in a range of from about 1 or about 12 carbon atoms, and may include as illustrative non-limiting examples methyl, ethyl, propyl, isopropyl, butyl, tertiary-butyl, pentyl, neopentyl, and hexyl. Cycloalkyl radicals may be those containing in a range of from about 4 to about 12 ring carbon atoms. Suitable cycloalkyl radicals may include cyclobutyl, cyclopentyl, cyclohexyl, methylcyclohexyl, and cycloheptyl. Aralkyl radicals may be those containing in a range of from about 7 to about 14 carbon atoms; these may include benzyl, phenylbutyl, phenylpropyl, and phenylethyl. Aryl radicals may include those in a range of from about 6 to about 14 ring carbon atoms. Suitable aryl radicals may include phenyl, biphenyl, and naphthyl, and may include a halogenated moiety, such as trifluoropropyl.

B-staging a curable material, and related terms and phrases, may include one or more of heating for a predetermined amount of time, optionally under vacuum; removing some or all of a solvent; at least partially solidifying the material; and/or advancing the cure or cross-linking of a curable resin from an uncured state to a partially, but not completely, cured state. Free of solvent, and like terms and phrases, may includes some or all of the solvent having been removed, for example, during B-staging.

A B-stageable film according to embodiments of the invention may include one or more curable (e.g., cross-linkable) resin. Suitable resins may include aromatic, aliphatic and cycloaliphatic resins. Resins may be described throughout the specification and claims either as a specifically named resin or as a composition, monomer or molecule having a moiety of the named resin.

In one embodiment, the resin may include one or more of epoxy resin, polydimethylsiloxane resin, acrylate resin, other organo-functionalized polysiloxane resin, polyimide resin, fluorocarbon resin, benzocyclobutene resin, fluorinated polyallyl ether, polyamide resin, polyimidoamide resin, phenol cresol resin, aromatic polyester resin, polyphenylene ether (PPE) resin, bismaleimide triazine resin, fluoro resin, or the like.

Curable and cross-linkable materials may include one or more epoxy resin, acrylate resin, polydimethyl siloxane resin, or other organo-functionalized polysiloxane resin that may cross-link via free radical polymerization, atom transfer, radical polymerization, ring-opening polymerization, ring-opening metathesis polymerization, anionic polymerization, or cationic polymerization.

The epoxy resin may include any organic system or inorganic system with epoxy functionality. In one embodiment, the epoxy resin may include an aromatic epoxy resin, a cycloaliphatic epoxy resin, aliphatic epoxy resin, or a mixture of two or more thereof.

Useful epoxy resins may include those that may be produced by reaction of a hydroxyl, carboxyl or amine-containing compound with epichlorohydrin in the presence of a basic catalyst, such as a metal hydroxide. Also included may be epoxy resins produced by reaction of a compound containing at least one and two or more carbon-carbon double bonds with a peroxide, such as a peroxyacid.

Suitable aromatic epoxy resins may be either monofunctional or polyfunctional. In one embodiment, the glass transition temperature (Tg) of a resultant cured film product may be increased by adding more aromatic epoxy resin, and may be decreased by using less aromatic epoxy resin.

Suitable aromatic epoxy resins may include one or more of cresol-novolak epoxy resins, bisphenol-A epoxy resins, bisphenol-F epoxy resins, phenol novolak epoxy resins, bisphenol epoxy resins, biphenyl epoxy resins, 4,4′-biphenyl epoxy resins, polyfunctional epoxy resins such as resorcinol diglycidyl ether, divinylbenzene dioxide, and 2-glycidylphenylglycidyl ether. Suitable trifunctional aromatic epoxy resins may include triglycidyl isocyanurate epoxy, VG3101L manufactured by Mitsui Chemical and the like. Suitable tetrafunctional aromatic epoxy resins may include ARALDITE MTO163 manufactured by Ciba Geigy and the like. A commercially available epoxy resin may be an epoxy cresol novolak sold by Sumitomo Chemical Limited (Tokyo, Japan).

Aromatic epoxy resins, if used, may be present in an amount in a range of from about 0.3 weight percent to about 0.5 by weight percent, from about 0.5 to about 1 weight percent, from about 1 to about 5 weight percent, from about 5 to about 10 weight percent, from about 10 weight percent to about 15 weight percent, from about 15 weight percent to about 25 weight percent, from about 25 weight percent to about 50 weight percent, from about 50 weight percent to about 75 weight percent, from about 75 weight percent to about 85 weight percent, from about 85 weight percent to about 95 weight percent, or greater than about 95 weight percent, based on the weight of the total resin content.

Cycloaliphatic epoxy resins may include at least one cycloaliphatic group. The cycloaliphatic epoxy resin may be either monofunctional or polyfunctional.

In one embodiment, a cycloaliphatic resin may include one or more of 3-(1,2-epoxyethyl)-7-oxabicyclo heptane; bis(7-oxabicyclo heptyl methyl)ester; 2-(7-oxabicyclo hept-3-yl)-spiro (1,3-dioxa-5,3′-(7)-oxabicyclo heptane; methyl 3,4-epoxy cyclohexane carboxylate, 3-cyclohexenyl methyl-3-cyclohexenyl carboxylate diepoxide, 2-(3,4-epoxy)cyclohexyl-5,5-spiro-(3,4-epoxy)cyclohexane-m-dioxane, 3,4-epoxy cyclohexyl alkyl-3,4-epoxy cyclohexane carboxylate, 3,4-epoxy-6-methyl cyclohexyl methyl-3,4-epoxy-6-methyl cyclohexane carboxylate, vinyl cyclohexane dioxide, bis(3,4-epoxy cyclohexyl methyl)adipate, bis(3,4-epoxy-6-methyl cyclohexyl methyl)adipate, exo-exo bis (2,3-epoxy cyclopentyl)ether, endo-exo bis (2,3-epoxy cyclopentyl) ether; 2,2-bis (4-(2,3-epoxy propoxy)cyclohexyl)propane, 2,6-bis(2,3-epoxy propoxy cyclohexyl-p-dioxane); 2,6-bis(2,3-epoxy propoxy)norbornene; diglycidyl ether of linoleic acid dimer; limonene dioxide; 2,2-bis(3,4-epoxy cyclohexyl) propane, dicyclopentadiene dioxide; 1,2-epoxy-6-(2,3-epoxy propoxy)-hexahydro-4,7-methanoindane; p-(2,3-epoxy)cyclo pentylphenyl-2,3-epoxy propyl ether; (2,3-epoxypropoxy)phenyl-5,6-epoxyhexahydro-4,7-methanoindane; o-(2,3-epoxy)cyclopentyl phenyl-2,3-epoxy propyl ether; 1,2-bis(5-(1,2-epoxy)-4,7-hexahydro methanoindanoxyl)ethane; cyclopentenyl phenyl glycidyl ether; cyclohexanediol diglycidyl ether; butadiene dioxide; dimethylpentane dioxide; diglycidyl ether; 1,4-butanediol diglycidyl ether; diethylene glycol diglycidyl ether; dipentene dioxide; or diglycidyl hexahydrophthalate. In one embodiment, the cycloaliphatic epoxy resin may include 3-cyclohexenylmethyl-3-cyclohexenylcarboxylate diepoxide.

Cycloaliphatic epoxy monomers, if used, may be present in an amount in a range of from about 0.3 weight percent to about 0.5 by weight percent, from about 0.5 to about 1 weight percent, from about 1 to about 5 weight percent, from about 5 to about 10 weight percent, from about 10 weight percent to about 15 weight percent, from about 15 weight percent to about 25 weight percent, from about 25 weight percent to about 50 weight percent, from about 50 weight percent to about 75 weight percent, from about 75 weight percent to about 85 weight percent, from about 85 weight percent to about 95 weight percent, or greater than about 95 weight percent, based on the weight of the total resin content.

Suitable aliphatic epoxy resins may include at least one aliphatic group, such as a C4-C20 aliphatic group. The aliphatic epoxy resin may be either monofunctional or polyfunctional. Suitable aliphatic epoxy resins may include one or more of butadiene dioxide, dimethylpentane dioxide, diglycidyl ether, polyglycol di-epoxide, 1,4-butane dioldiglycidyl ether, diethylene glycol diglycidyl ether, and dipentene dioxide. Dow markets such aliphatic epoxy resins under trade names such as DER 732 and DER 736, which may be colloquially known as flexibilizers.

Aliphatic epoxy resin, if used, may be present in an amount in a range of from about 0.3 weight percent to about 0.5 by weight percent, from about 0.5 to about 1 weight percent, from about 1 to about 5 weight percent, from about 5 to about 10 weight percent, from about 10 weight percent to about 15 weight percent, from about 15 weight percent to about 25 weight percent, from about 25 weight percent to about 50 weight percent, from about 50 weight percent to about 75 weight percent, from about 75 weight percent to about 85 weight percent, from about 85 weight percent to about 95 weight percent, or greater than about 95 weight percent, based on the weight of the total resin content.

Suitable silicone-epoxy resins may be utilized and may be of the formula:
MₐM′_{b}D_{c}D′_{d}TₑT′_{f}Q_{g}
where the subscripts a, b, c, d, e, f and g may be zero or a positive integer, subject to the limitation that the sum of the subscripts b, d and f may be one or greater; where:
M has the formula: R¹ R² R³SiO_{1/2},
M′ has the formula: (Z)R⁴ R⁵SiO_{1/2},
D has the formula: R6 R⁷ R⁸SiO_{1/2},
D′ has the formula: (Z)R⁹SiO_{2/2},
T has the formula: R¹⁰SiO_{3/2},
T′ has the formula: (Z)SiO_{3/2},
and Q has the formula: SiO_{4/2},
   where each of R¹ through R¹⁰ is independently at each occurrence one of a hydrogen atom, C1-C22 alkyl, C1-C22 alkoxy, C2-C22 alkenyl, C6-C14 aryl, C6-C22 alkyl-substituted aryl, or a C6-C22 arylalkyl. Groups of which may be halogenated, for example, fluorinated to contain fluorocarbons such as C1-C22 fluoroalkyl, or may contain amino groups to form aminoalkyls, for example aminopropyl or aminoethylaminopropyl, or may contain polyether units of the formula (CH₂CHRO)ₖ where R may be methyl or hydrogen, and k may be in a range of from about 4 to about 20; and Z is a pendant group that may be functional, such as an oxirane (or epoxy) group.

Two or more differing epoxy resins may be used in combination, e.g., a mixture of an alicyclic epoxy and an aromatic epoxy. Such a combination may affect, for example, transparency and flow properties. In one embodiment, an epoxy resin may include three or more functionalities. Increasing functionality may form a B-stageable film having one or more of a relatively low CTE, relatively improved fluxing performance, and a high glass transition temperature.

The total resin content in a film according to an embodiment of the invention may be used as the basis for amounts of other ingredients. In one embodiment, the resin content may be in an amount in a range of from about 0.3 weight percent to about 0.5 by weight percent, from about 0.5 to about 1 weight percent, from about 1 to about 5 weight percent, from about 5 to about 10 weight percent, from about 10 weight percent to about 15 weight percent, from about 15 weight percent to about 25 weight percent, from about 25 weight percent to about 50 weight percent, from about 50 weight percent to about 75 weight percent, from about 75 weight percent to about 85 weight percent, from about 85 weight percent to about 95 weight percent, or greater than about 95 weight percent, based on the weight of the total resin content. The amount of resin may be adjusted, selected, or determined based on such factors as the molar amount of other ingredients and application specific parameters.

A B-stageable film may include a solvent. Suitable solvents may include one or more organic solvents, such as 1-methoxy-2-propanol, methoxy propanol acetate, butyl acetate, methoxyethyl ether, methanol, ethanol, isopropanol, ethyleneglycol, ethylcellosolve, methylethyl ketone, cyclohexanone, benzene, toluene, xylene, and cellosolves such as ethyl acetate, cellosolve acetate, butyl cellosolve acetate, carbitol acetate, and butyl carbitol acetate, and combinations thereof. These solvents may be used either singly or in the form of a combination of two or more members.

Solvent may be present in the B-stageable film in a weight percent of greater than about 1 percent, based on the total weight of the composition. In one embodiment, the amount of solvent in the B-stageable film may be in a range of from about 1 weight percent to about 10 weight percent, from about 10 weight percent to about 25 weight percent, from about 25 weight percent to about 50 weight percent, or greater than about 50 weight percent.

Subsequent to B-staging, residual or insignificant amounts of solvent may remain, and are included by the phrase solvent-free because a significant portion of the solvent may have been removed. Further, because a blend of solvents having differing boiling points may be used, some of the higher boiling point solvents may be not be as readily extractable relative to the lower boiling point solvent. Solvents having polar groups or reactive groups may remain in the curable composition after solvent extract to form a B-staged film.

A hardener may be included in a film in one embodiment. In one embodiment, the hardener may include an epoxy hardener. Epoxy hardeners may include one or more of an amine epoxy hardener, a phenolic or novolak resin hardener, or a carboxylic acid anhydride hardener. Optionally, one or both of a cure catalyst, curing agent, or an organic compound containing a hydroxyl moiety may be used in combination with the hardener.

A suitable amine epoxy hardeners may include one or both of aromatic amines or aliphatic amines. Aromatic amines may include one or more of m-phenylene diamine, 4,4′-methylene dianiline, diamino diphenyl sulfone, diamino diphenyl ether, toluene diamine, or dianisidene. Aliphatic amines may include one or more of ethyleneamines, cyclohexyldiamines, alkyl substituted diamines, menthane diamine, isophorone diamine, and hydrogenated versions of the aromatic diamines.

Suitable phenolic resin hardeners may include a phenol-formaldehyde condensation product, such as a novolak or cresol resin. These resins may be condensation products of different phenols with various molar ratios of formaldehyde. A commercially available novolak hardener may be a phenol novolak resin hardener sold as TAMANOL 758 or HRJ 1583 by, for example, Arakawa Chemical (USA) Inc. (Chicago, Ill.).

Suitable carboxylic acid anhydrides may be prepared by reacting a carboxylic acid with an acyl halide, or by dehydrating a carboxylic acid, that is, eliminate water between two carboxylic acid molecules to form the anhydride. Alternatively, carboxylic acid anhydrides may be obtained commercially from common chemical suppliers. Suitable carboxylic acid anhydrides may include one or more aromatic carboxylic acid anhydride, aliphatic carboxylic acid anhydride, or cycloaliphatic carboxylic acid anhydride.

Suitable hydroxyl-containing compounds useful with the hardeners may be those that do not interfere with the resin matrix of the present composition. Such hydroxy-containing monomers may include hydroxy aromatic compounds such as phenol substituted with one or more of R¹, R², R³, R⁴, or R⁵ where each R¹, R², R³, R⁴, or R⁵ may be independently a C1-C10 branched or chain aliphatic or aromatic group, or hydroxyl. Suitable such hydroxyl aromatic compounds may include, but are not limited to, hydroquinone, methyl hydroquinone, resorcinol, methyl resorcinol catechol, and methyl catechol.

In one embodiment, the hardener may serve to facilitate fluxing of solder balls during cure. That is, a curing temperature may be selected to be about the melt point temperature of a solder ball that may be disposed in the B-stageable film. Melting of the solder ball may form an electrical contact. The hardener may behave as a flux to enhance or improve the quality of the electrical contact formed relative to a contact formed without the presence of a fluxing curing agent.

The hardener, if used, may be present in an amount in a range of from about 0.1 weight percent to about 0.5 by weight percent, from about 0.5 to about 1 weight percent, from about 1 to about 3 weight percent, from about 3 to about 5 weight percent, from about 5 weight percent to about 10 weight percent, from about 10 weight percent to about 15 weight percent, from about 15 weight percent to about 25 weight percent, from about 25 weight percent to about 50 weight percent, or greater than about 50 weight percent, based on the weight of the total resin content.

Another ingredient that the composition for making the B-stageable film of the invention may include may be a curing agent. Suitable curing agents may include one or more free radical initiators, such as azo compounds, peroxides, and the like. Suitable azo compounds for the curing agent may include azobisisobutyronitrile.

Suitable peroxides may include on or more organic peroxide, such as those having the formula R—O—O—H or R—O—O—R′. In one embodiment, the organic peroxide may include one or more of diacyl, peroxydicarbonate, monoperoxycarbonate, peroxyketal, peroxyester, or dialkyl peroxide. In one embodiment, the organic peroxide may include one or more of dicumyl peroxide, cumyl hydroperoxide, t-butyl peroxy benzoate, or ketone peroxide. A commercially available organic ketone peroxide is NOROX® MEKP-9, from Norac Inc. (Helena, Ark.). In one embodiment, the peroxide may include hydroperoxide.

The curing agent, if used, may be present in an amount greater than about 0.5 weight percent. In one embodiment, the curing agent may be present in a range of from about 0.1 weight percent to about 0.5 by weight percent, from about 0.5 to about 1 weight percent, from about 1 to about 3 weight percent, from about 3 to about 5 weight percent, from about 5 weight percent to about 10 weight percent, from about 10 weight percent to about 15 weight percent, from about 15 weight percent to about 25 weight percent, from about 25 weight percent to about 50 weight percent, or greater than about 50 weight percent, based on the weight of the total resin content.

A cure catalyst may be included in the B-stageable film. Suitable cure catalysts may include one or more amine, imidazole, imidazolium salt, phosphine, metal salt, or salt of nitrogen-containing compound. A metal salt may include, for example, aluminum acetyl acetonate (Al(acac)3). The nitrogen-containing molecule may include, for instance, amine compounds, di-aza compounds, tri-aza compounds, polyamine compounds and combinations thereof. The acidic compounds may include phenol, organo-substituted phenols, carboxylic acids, sulfonic acids and combinations thereof.

Suitable amines may include one or more nitrogen-containing molecule, for example, a mono amine, aniline, pyridine, pyrimidine, pyrrole, pyrrolidine, indole, or aza compound. In one embodiment, the nitrogen-containing molecule may include one or more of glycine, pentafluoroaniline, methyl-aniline, diethylenetriamine, diaminodiphenylamine, 1,4-diazabucyclo [2,2,2] octane, 1-methyl imidazole, 2-methyl imidazole, 1-phenyl imidazole, 1,8-diazabicyclo(5,4,0)undec-7-ene (DBU), and the like. In one embodiment, the amine may include one or more non-tertiary amines. In one embodiment, the amine may consistent essentially of an imidazole. A suitable diaza nitrogen-containing molecule may have the structure shown below, or the like.

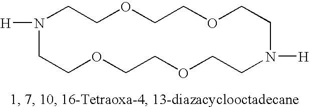

In one embodiment, the catalyst may include a salt of a nitrogen-containing compound. Such salts may include, for example, 1,8-diazabicyclo(5,4,0)-7-undecane. Salts of nitrogen-containing compounds may be available commercially, for example, as Polycat SA-1 and Polycat SA-102 available from Air Products. In one embodiment, the catalyst may include one or more of triphenyl phosphine, methylimidazole, or dibutyl tin dilaurate.

Suitable phosphines may include one or more phosphorus-containing composition, for example, tributylphosphine, diphenyl butylphosphine, triphenylphosphine and the like. In one embodiment, the phosphines may include one or more non-tertiary phosphines. In one embodiment, the phosphine may consistent essentially of one or more non-tertiary phosphines.

The cure catalyst, if used, may be present in an amount greater than about 0.5 weight percent. In one embodiment, the cure catalyst may be present in a range of from about 0.1 weight percent to about 0.5 by weight percent, from about 0.5 to about 1 weight percent, from about 1 to about 3 weight percent, from about 3 to about 5 weight percent, from about 5 weight percent to about 10 weight percent, from about 10 weight percent to about 15 weight percent, from about 15 weight percent to about 25 weight percent, from about 25 weight percent to about 50 weight percent, or greater than about 50 weight percent, based on the weight of the total resin content.

The B-stageable film of the invention may include a filler admixed together with the other film ingredients. Suitable fillers may include one or more of alumina, boron nitride, silica, talc, zinc oxide, and the like. Other suitable filler may include particulate comprising a metal, such as indium, aluminum, gallium, boron, phosphorus, tin, or alloys, oxides or mixtures of two or more thereof.

Suitable silicas distributed in the United States of America by JCI USA Incorporated (a distributor for Nippon, located in Tokyo, Japan) under the trade names LE O3S, LE 05S, LE 10, and LE 25, may be alumina under the trade name DA W05 from Denka Corporation, or may be aluminum under the trade name Al 104 from Atlantic Equipment Engineers.

The filler may include silica. Suitable silica may include one or more of fused silica, fumed silica, or colloidal silica. The filler may have an average particle diameter of less than about 500 micrometers. In one embodiment, the filler may have an average particle diameter in a range of from about 1 nanometer to about 5 nanometers, from about 5 nanometers to about 10 nanometers, from about 10 nanometers to about 50 nanometers

Filler may be treated with a functionalizing or compatiblizing agent, and may be further treated with a passivating agent. A suitable compatiblizing agent may include organoalkoxysilane, and a suitable passivating agent may include a silizane.

Suitable organoalkoxysilanes may be included within the formula:
(R¹¹)ₐSi(OR¹²)₄₋ₐ,
where R¹¹ is independently at each occurrence a C1-C18 monovalent hydrocarbon radical optionally further functionalized with alkyl acrylate, alkyl methacrylate or epoxide groups or C6-C14 aryl or alkyl radical, R¹² is independently at each occurrence a C1-C18 monovalent hydrocarbon radical or a hydrogen radical and “a” may be a whole number equal to 1 to 3 inclusive. Suitable organo alkoxy silanes may include one or more of phenyl trimethoxysilane, 2-(3,4-epoxy cyclohexyl)ethyltrimethoxy silane, 3-glycidoxy propyl trimethoxy silane, or methacryloxy propyl trimethoxy silane.

The organoalkoxysilane may be used in a range of from about 0.5 weight percent to about 1 weight percent, from about 1 weight percent to about 5 weight percent, from about 5 weight percent to about 20 weight percent, from about 20 weight percent to about 30 weight percent, or greater than about 30 weight percent, based on the weight of silicon dioxide contained in the filler.

Functionalization of filler may be performed by adding the functionalizing agent to, for example, filler dispersed in an aqueous aliphatic solvent solution in the weight ratio described above. The resulting composition may include the functionalized filler and the functionalizing agent in solution, and may be referred to as a pre-dispersion. The aliphatic solvent may include one or more of isopropanol, t-butanol, 2-butanol, and the like, and may include further one or more of 1-methoxy-2-propanol, 1-methoxy-2-propyl acetate, toluene, and combinations thereof. The amount of aliphatic alcohol may be in a range of from about 1 fold to about 10 fold of the amount of silicon dioxide present in the aqueous filler pre-dispersion.

The resulting treated or functionalized filler may be treated further with an acid, or a base, to neutralize the pH. The acid, base, or other catalyst may promote condensation of silanol and alkoxysilane groups to drive the functionalization process. Suitable catalysts may include, for example, organo-titanate or organo-tin compounds such as tetrabutyl titanate, titanium isopropoxy bis (acetyl acetonate), or dibutyltin dilaurate. In some cases, stabilizers such as 4-hydroxy-2,2,6,6-tetramethyl piperidinyloxy (4-hydroxy TEMPO) may be added to this pre-dispersion. The resulting pre-dispersion may be heated in a range of from about 50 degrees Celsius to about 100 degrees Celsius for a period in a range of from about 1 hour to about 5 hours.

Once cooled, the pre-dispersion may be transparent and/or colorless. The pre-dispersion may be treated to form a final dispersion. For instance, curable monomers or oligomers may be added to the pre-dispersion. Optionally, more aliphatic solvent may be added to the pre-dispersion. This final dispersion of the functionalized filler may be treated with acid or base or with ion exchange resins to remove acidic or basic impurities.

The final dispersion composition can be hand-mixed or mixed by standard mixing equipment such as dough mixers, chain can mixers, and planetary mixers. The blending of the dispersion components can be performed in batch, continuous, or semi-continuous mode.

Concentration of the final dispersion of the functionalized filler may be performed under vacuum in a range of from about 0.5 Torr (about 0.5 mm Hg) to about 250 Torr (about 250 mm Hg) and at a temperature in a range of from about 20 degrees Celsius to about 140 degrees Celsius to remove any low boiling components such as solvent or residual water. The concentrated end product of functionalized filler may be added to a curable monomer. Removal of low boiling components may include removal of low boiling components in amounts sufficient to provide a concentrated filler dispersion containing from about 15 weight percent to about 80 weight percent of filler relative to total weight. Partial removal of low boiling components may include removal of at least about 10 weight percent of the total amount of low boiling components.

For a composition that may include functionalized filler, the amount of silicon dioxide in the final B-stageable film may be greater than about 1 weight percent based on the total weight of the composition. In one embodiment, the amount of silica may be in a range of from about 1 weight percent to about 25 weight percent, from about 25 weight percent to about 50 weight percent, from about 50 weight percent to about 75 weight percent, or from about 75 weight percent to about 90 weight percent. In one embodiment, filler may be uniformly distributed throughout the disclosed composition, and this distribution remains stable at room temperature. Uniformly distributed may include the absence of any visible precipitate. In one embodiment, the dispersions may be transparent. Transparent includes the ability to see and distinguish features while looking through a predetermined length of the material. In one embodiment, transparent is defined according to ASTM D 1746-97 and/or ASTM D 1003-00, as applicable.

The pre-dispersion and/or the final dispersion of the functionalized filler may be further treated. Low boiling components may be at least partially removed, and subsequently, an appropriate capping agent that may react with residual hydroxyl (silanol) functionality on the functionalized filler surface may be added in an amount in a range of from about 0.05 times to about 10 times the amount by weight of filler present in the pre-dispersion or the final dispersion.

An effective amount of capping agent caps the functionalized filler and capped functionalized filler may be defined herein as a functionalized filler in which from about 10 percent to about 35 percent of the free hydroxyl groups present in the corresponding uncapped functionalized filler have been functionalized by reaction with a capping agent. In one embodiment, a residual surface hydroxyl content may be less than about 4 per square nanometer.

The functionalization may make otherwise phase incompatible filler relatively more compatible with a matrix material. Formulations, which may include the capped or passivated functionalized filler, may have improved room temperature stability relative to analogous formulations in which the filler has not been capped. Capping the functionalized filler may affect cured properties of the curable resin formulation. These properties may include room temperature stability of the filled resin formulation, glass transition temperature, heat deflection temperature, chemical resistance, electrical resistance, appearance, surface texture, and the like.

Suitable capping agents may include one or more hydroxyl reactive materials, such as silylating agents. Suitable silylating agents may include one or more of hexamethyldisilazane (HMDZ), tetramethyldisilazane, divinyltetramethyl disilazane, diphenyl tetramethyl disilazane, N-(trimethylsilyl)diethylamine, 1-(trimethylsilyl)imidazole, trimethyl chlorosilane, pentamethyl chloro disiloxane, pentamethyl disiloxane, and the like. In one embodiment, hexamethyldisilazane may be the capping agent.

Where the dispersion has been further functionalized, e.g. by capping, at least one curable monomer may be added to form the final dispersion. The dispersion may be heated in a range of from about 20 degrees Celsius to about 140 degrees Celsius for a period in a range of from about 0.5 hours to about 48 hours. The resultant mixture may be filtered. The mixture of the functionalized filler in the curable monomer may be concentrated at a pressure in a range of from about 0.5 Torr (about 0.5 mm Hg) to about 250 Torr (about 250 mm Hg) to form the final concentrated dispersion. During this process, lower boiling components such as solvent, residual water, byproducts of the capping agent and hydroxyl groups, excess capping agent, and combinations thereof may be removed to give a dispersion of capped functionalized filler containing from about 15% to about 75% filler.

Suitable organic compounds utilized as the hydroxyl-containing moiety may include alcohols such as diols, high boiling alkyl alcohols containing one or more hydroxyl groups and bisphenols. The alkyl alcohols may be straight chain, branched or cycloaliphatic and may contain from 2 to 12 carbon atoms. Suitable such alcohols may include but may be not limited to ethylene glycol; propylene glycol, i.e., 1,2- and 1,3-propylene glycol; 2,2-dimethyl-1,3-propane diol; 2-ethyl, 2-methyl, 1,3-propane diol; 1,3- and 1,5-pentane diol; dipropylene glycol; 2-methyl-1, 5-pentane diol; 1,6-hexane diol; dimethanol decalin, dimethanol bicyclo octane; 1,4-cyclohexane dimethanol and particularly its cis- and trans-isomers; triethylene glycol; 1,10-decane diol; and combinations of any of the foregoing. Further Suitable diols may include bisphenols.

An illustrative, non-limiting example of a suitable bisphenol may include a dihydroxy-substituted aromatic hydrocarbon. In one embodiment, the dihydroxy-substituted aromatic hydrocarbons may include 4,4′-(3,3,5 trimethyl cyclohexylidene)diphenol; 2,2-bis(4-hydroxyphenyl)propane (bisphenol A); 2,2-bis(4-hydroxyphenyl)methane (bisphenol F); 2,2-bis(4-hydroxy-3,5-dimethylphenyl)propane; 2,4′-dihydroxy diphenylmethane; bis(2-hydroxyphenyl)methane; bis(4-hydroxyphenyl)methane; bis (4-hydroxy-5-nitrophenyl)methane; bis(4-hydroxy-2,6-dimethyl-3-methoxyphenyl)methane; 1,1-bis(4-hydroxyphenyl)ethane; 1,1-bis(4-hydroxy-2-chlorophenyl ethane; 2,2-bis(3-phenyl-4-hydroxyphenyl)propane; bis(4-hydroxy phenyl)cyclohexyl methane; 2,2-bis(4-hydroxyphenyl)-1-phenylpropane; 2,2,2′,2′-tetrahydro-3,3,3′,3′-tetramethy-1,1′-spiro bi[1H-indene]-6,6′-diol; 2,2-bis(4-hydroxy-3-methylphenyl)propane (DMBPC); and C₁₋₁₃ alkyl-substituted resorcinols. Combinations of organic compounds containing a hydroxyl moiety may be used.

The filler may be present in an amount greater than about 0.5 weight percent. In one embodiment, the filler may be present in an amount in a range of from about 0.5 weight percent to about 10 weight percent, from about 10 weight percent to about 20 weight percent, from about 20 weight percent to about 30 weight percent, from about 30 weight percent to about 40 weight percent, from about 40 weight percent to about 50 weight percent, from about 50 weight percent to about 60 weight percent, from about 60 weight percent to about 70 weight percent, from about 70 weight percent to about 80 weight percent, from about 80 weight percent to about 90 weight percent, or greater than about 90 weight percent, based on the total weight of the composition.

A reactive organic diluent may also be added to the total curable epoxy formulation to decrease the viscosity of the composition. Suitable reactive diluents may include one or more of 3-ethyl-3-hydroxymethyl-oxetane, dodecylglycidyl ether, 4-vinyl-1-cyclohexane diepoxide, di(Beta-(3,4-epoxycyclo hexyl)ethyl)-tetramethyldisiloxane, and combinations thereof. Reactive organic diluents may also may include monofunctional epoxies and/or compounds containing at least one epoxy functionality. Representative Suitable such diluents may include one or more of alkyl derivatives of phenol glycidyl ethers such as 3-(2-nonyl phenyloxy)-1,2-epoxypropane or 3-(4-nonylphenyloxy)-1,2-epoxypropane. Other diluents which may be used may include glycidyl ethers of phenol itself and substituted phenols such as 2-methyl phenol, 4-methyl phenol, 3-methyl phenol, 2-butyl phenol, 4-butyl phenol, 3-octyl phenol, 4-octyl phenol, 4-t-butyl phenol, 4-phenyl phenol, and 4-(phenyl isopropylidene)phenol.

Reactive diluent, if used, may be present in an amount greater than about 0.5 weight percent based on the total weight of the composition. In one embodiment, the diluent may be present in an amount in a range of from about 0.5 weight percent to about 1 weight percent, from about 1 weight percent to about 1.5 weight percent, from about 1.5 weight percent to about 2.5 weight percent, from about 2.5 weight percent to about 3.5 weight percent, from about 3.5 weight percent to about 4.5 weight percent, from about 4.5 weight percent to about 5.5 weight percent, from about 5.5 weight percent to about 10 weight percent, from about 10 weight percent to about 15 weight percent, from about 15 weight percent to about 20 weight percent, or greater than about 20 weight percent, based on the total weight of the composition.

A B-stageable film may include an adhesion promoter. In on embodiment, the adhesion promoter may include one or more of trialkoxyorganosilane, such as γ-aminopropyl trimethoxy silane, 3-glycidoxypropyl trimethoxy silane, or bis (trimethoxy silyl propyl) fumarate, and the like.

Adhesion promoters, if used, may be present in an amount greater than about 0.5 weight percent based on the total weight of the composition. In one embodiment, the adhesion promoters may be present in an amount in a range of from about 0.5 weight percent to about 1 weight percent, from about 1 weight percent to about 1.5 weight percent, from about 1.5 weight percent to about 2.5 weight percent, from about 2.5 weight percent to about 3.5 weight percent, from about 3.5 weight percent to about 4.5 weight percent, from about 4.5 weight percent to about 5.5 weight percent, from about 5.5 weight percent to about 10 weight percent, from about 10 weight percent to about 15 weight percent, from about 15 weight percent to about 20 weight percent, or greater than about 20 weight percent, based on the total weight of the composition.

A B-stageable film may include a flame retardant. Suitable flame retardants may include one or more of triphenyl phosphate (TPP), resorcinol diphosphate (RDP), bisphenol-a-diphosphate (BPA-DP), organic phosphine oxide, halogenated resin (e.g., tetrabromobisphenol A), metal oxide, metal hydroxide, and the like. Other suitable flame retardants may include a compound selected from the class of phosphoramide compounds.

Flame retardants, if used, may be present in an amount greater than about 0.5 weight percent based on the total weight of the composition. In one embodiment, the flame retardants may be present in an amount in a range of from about 0.5 weight percent to about 1 weight percent, from about 1 weight percent to about 1.5 weight percent, from about 1.5 weight percent to about 2.5 weight percent, from about 2.5 weight percent to about 3.5 weight percent, from about 3.5 weight percent to about 4.5 weight percent, from about 4.5 weight percent to about 5.5 weight percent, from about 5.5 weight percent to about 10 weight percent, from about 10 weight percent to about 15 weight percent, from about 15 weight percent to about 20 weight percent, or greater than about 20 weight percent, based on the total weight of the composition.

Suitable heat-dissipating components may include one or more of a heat sink, a heat radiator, heat spreader, heat pipe, or a Peltier heat pump. Suitable heat-generating devices may include one or more of an integrated chip, a power chip, power source, light source (e.g., LED, fluorescent, or incandescent), motor, sensor, capacitor, fuel storage compartment, conductor, inductor, switch, diode, or transistor.

In one embodiment, disparate temperature regions across a heat-generating device surface may be caused by, for example, non-uniform power distribution. For example, on a one centimeter by one centimeter integrated circuit chip dissipating a total of about 100 watts, the total thermal dissipation may be, on average, about 1 watt per square millimeter. But, that is only true of an average, or if the power density was equally distributed across the chip surface. Integrated circuits having various types of circuits, such as IO, memory, registers, and arithmetic logic, have differing power density regions. The non-uniform power density or distribution may cause power peaks and thermal loads in localized regions that are higher or lower than other regions and than the total average thermal dissipation for the chip. A heat spreader may thermally planarize disparate temperature regions across a surface.

A B-stageable film may be applied by to a heat transfer surface by, for example, one or more surface mount technology (SMT) methods. The SMT methods may include a screen printing method, a side-capillary flow method, a central-well method, and a central-line method. In one embodiment, a cured film layer may be continuous or discontinuous.

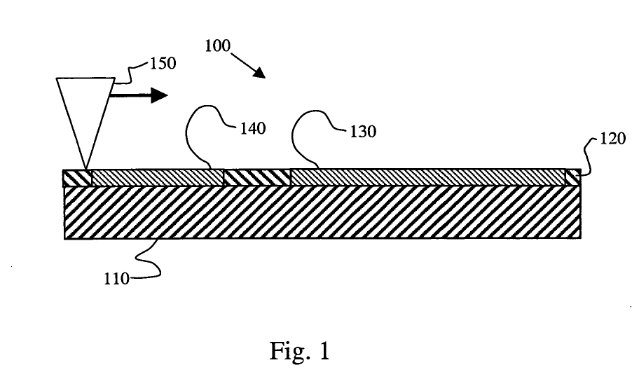

With reference to FIG. 1, a screen printing method may be used to form a sub assembly 100. A substrate 110 may have a stencil 120 aligned thereon to apply a B-stageable film into a first portion 130 and a second portion 140 on a heat transfer surface. A doctor blade 150 may be used to apply the B-stageable film material to the surface of the stencil 120, and may remove excess material when drawn across the stencil surface in the direction indicated by the directional arrow.

The thickness of the applied material may be controlled during application. In one embodiment, changing the thickness of the stencil may allow for control over the thickness of the material deposited on the heat transfer surface. The film thickness may be uniform, or may differ from area to area in response to predetermined criteria in controlled manner.

The printed B-stageable film may be B-staged, for example, by removal of most or all of the solvent, partially cross-linking a reactive monomer, and/or partially solidifying the B-stageable film. A vacuum oven may be used to apply a negative pressure, heat, or both during B-staging.

In one embodiment, after B-staging, the B-staged film may be tack-free, and may be flexible and not brittle. A heat transfer surface having the B-staged film adhered thereto may be cut, for example, by sawing into individual dies. The B-staged film may not be friable, and may not splinter, crack, or delaminate at the cut edges of the die. Further, the heat produced by cutting may be insufficient to initiate cure of the B-staged film. The individually cut dies may be shipped, handled, stored, and the like. The tack-free properties of the B-staged film may prevent sticking to packing materials and the like.

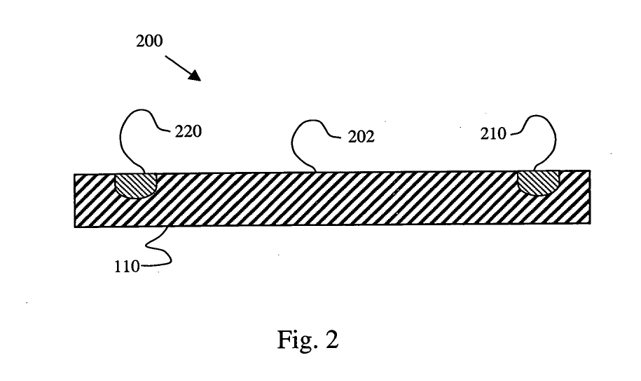

A sub assembly 200 may be formed using a side-capillary flow method as shown with reference to FIG. 2. Like parts are indicated by the use of the same reference numerals. On the substrate 110, a pre-formed groove or channel may be formed proximate to a peripheral edge of the substrate heat transfer surface 202. Into the groove or channel, a B-stageable film 210, 220 may be applied.

The B-stageable film may be B-staged, for example, by removal of most or all of the solvent, partially cross-linking a reactive monomer, and/or partially solidifying the B-stageable film. The heat transfer surface may be aligned with a complimentary surface, and the exposed surface of the B-stageable film may be contacted thereto to form an assembly. During a post-assembly cure process, the B-stageable film may soften and/or flow in response to heat to fill one or more gaps by a capillary flow action across the heat transfer surface.

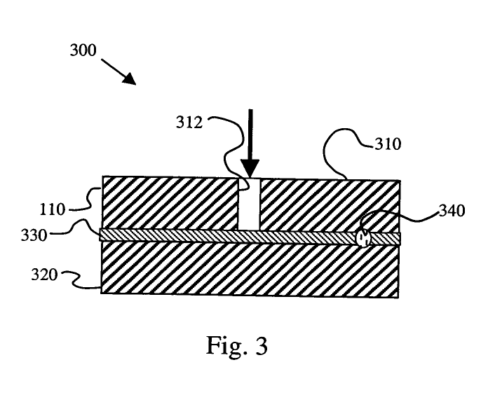

FIG. 3 shows an assembly 300 that includes a substrate 110 with a heat-dissipating surface 310 that defines a centrally located aperture 312. The substrate 110 may be aligned and in thermal communication with a heat-generating substrate 320. A heat transfer surface of the substrate 110 may be opposite the heat-dissipating surface 310, and in cooperation with the heat-generating substrate 320 may define a volume filled with a B-stageable film 330. The B-stageable film may be applied through the aperture 312 in the direction indicated by the directional arrow using the central-well method. The central-well method may be useful for a heat transfer surface with a relatively large heat transfer surface. To minimize negative impact on the heat transfer path, the diameter of the aperture 312 may be as small as possible (e.g., <3 mm). In one embodiment, a circular thermal tape with a diameter larger than the though-hole may be used to block the well on the active side.

A solvent free B-stageable film may be applied through the aperture 312 and B-staged. Alternatively, a solvated B-stageable material may be disposed in the aperture and B-staged to remove the solvent. During post-assembly cure, the B-stageable film may soften and flow into the volume between the heat-generating substrate and the heat-dissipating surface in response to capillary flow. A solder ball 340 may facilitate electrical and/or thermal communication across the volume. Reduced air bubble density may reduce the defect density (e.g., voids) inside a B-staged film layer.

A central-line method may be similar to the central-well method except that the central-line method uses a though-line for capillary flow instead of an aperture. An extension of the central-line method may use two separate heat-dissipating components with abutting adjacent edges. The mating edge of these two heat-dissipating components may act as the central line for capillary flow of a B-stageable film.

A B-stageable film application process may be integrated into a manufacturing process back-end during the making of a heat-dissipating component. Surface mount technology (SMT) may be employed in order to pre-apply a B-stageable film) onto a heat transfer surface. The resultant heat-dissipating component, with the B-stageable film applied and subsequently B-staged, may be aligned with, and adjacent to, an electronic device for assembling them.

As illustrated by FIGS. 1, 2, and 3, one or more component having a heat transfer surface may be provided with various apertures and textures, such as holes, grooves, channels, and the like, to control and/or direct flow of the B-stageable film during B-staging.

B-staging the B-stageable film may be for a sufficient time at a sufficient temperature and a sufficient vacuum to achieve the heat-dissipating component having a B-staged resin film adhered to the heat-dissipating component, where the film may be free of solvent.

B-staging of the B-stageable film may be performed at a temperature greater than room temperature. In one embodiment, the B-staging temperature may be in a range of from about 50 degrees Celsius to about 65 degrees Celsius, from about 65 degrees Celsius to about 80 degrees Celsius, from about 80 degrees Celsius to about 220 degrees Celsius, from about 220 degrees Celsius to about 235 degrees Celsius, from about 235 degrees Celsius to about 250 degrees Celsius, or greater than about 250 degrees Celsius.

B-staging of the B-stageable film may be performed for a time that is greater than about 30 seconds. In one embodiment, the B-staging time may be in a range of from about 1 minute to about 10 minutes, from about 10 minutes to about 30 minutes, from about 30 minutes to about 60 minutes, from about 60 minutes to about 70 minutes, from about 70 minutes to about 240 minutes, from about 240 minutes to about 270 minutes, from about 270 minutes to about 300 minutes, or greater than about 300 minutes.

B-staging of the B-stageable film may be performed at a controlled pressure. In one embodiment, the pressure may be about ambient pressure. In one embodiment, the pressure may be a negative pressure of less than about 10 mm Hg (about 10 Torr). In one embodiment the pressure may be in a range of from about 10 mm Hg (about 10 Torr) to about 50 mm Hg (about 50 Torr), from about 50 mm Hg (about 50 Torr) to about 75 mm Hg (about 75 Torr), from about 75 mm Hg (about 75 Torr) to about 200 mm Hg (about 200 Torr), from about 200 mm Hg (about 200 Torr) to about 225 mm Hg (about 225 Torr), from about about 225 mm Hg (about 225 Torr) fo about 250 mm Hg (about 250 Torr), or greater than about 250 mm Hg (about 250 Torr). In one embodiment, B-staging may be effected at about 95 degrees Celsius at less than about 10 mm Hg (less than about 10 Torr), for about 90 minutes.

In one embodiment, after alignment of an assembled component, a cure may be effected in order to allow the pre-applied, B-staged film to flow sufficiently to fill the gap between respective surfaces of the heat-dissipating component and the electronic device. In one embodiment, the B-stage film may flow and wet the volume between the heat-generating device and a substrate, such as a PCB, on which the device is mounted. In one embodiment, the B-staged film may not flow in response to the application of heat, or may cure with no change in shape or size.

Cure may include subjecting the assembly to energy, such as heat or ultraviolet light. Curing may be for a sufficient time with a sufficient amount of energy to achieve a cured resin film adhering an electronic device to a heat-dissipating component.

If thermal energy is used for curing, the cure may be effected at a temperature of greater than about 50 degrees Celsius. In one embodiment, the cure temperature may be in a range of from about 50 degrees Celsius to about 65 degrees Celsius, from about 65 degrees Celsius to about 100 degrees Celsius, from about 100 degrees Celsius to about 200 degrees Celsius, from about 200 degrees Celsius to about 235 degrees Celsius, from about 235 degrees Celsius to about 250 degrees Celsius, or greater than about 250 degrees Celsius.

Cure may be effected in a time of less than about from about 30 seconds, in a range of from about 30 seconds to about 10 minutes, from about 10 minutes to about 30 minutes, from about 30 minutes to about 120 minutes, from about 120 minutes to about 240 minutes, from about 240 minutes to about 300 minutes, or greater than about 300 minutes. In one embodiment, a cure may be effected by increasing the temperature of a curable composition to be in a range of from about 140 degrees Celsius to about 160 degrees Celsius, for a time in a range of from about 40 minutes to about 60 minutes.

Curing may be at a predetermined pressure, such as at ambient pressure. In one embodiment, pressure may be added for the cure by loading a weight on the 3-component assembly, depending on the end use application by holding the assembly together with a metallic clip which exerts 1 or 2 pounds of force.

Although a temperature for the B-staging and the particular temperature for the cure may differ with reference to the particular polymeric resin system, in general, a B-staging temperature may be lower than a cure temperature. A reason may be that the purpose of the B-staging may be to remove most or all of the solvent, but not to fully polymerize reactive moieties in the resin. On the other hand, the purpose of the cure may be mainly to polymerize the resin for the final B-stageable film. One or more epoxies, a catalyst, and a hardener may react and cross-link during the cure to form a solid B-stageable film layer that adheres together the heat-dissipating component and the electronic device. The cure may provide robust mechanical adhesion and/or chemical adhesion for the assembled sandwich.

Bond line thickness (BLT) of the B-stageable film of the interface may be controlled to be greater than about 10 micrometers. In one embodiment, the BLT may be in a range of from about 10 micrometers to about 15 micrometers, from about 15 micrometers to about 20 micrometers, from about 20 micrometers to about 20 micrometers, from about 50 micrometers to about 60 micrometers, or from about 60 micrometers to about 70 micrometers, or greater than about 70 micrometers. In one embodiment, a cured film layer may have regions that are thicker in some places than in other places.

In one embodiment, thermal performance, shear strength, electrical conductivity (dielectric strength), flexibility, and adhesive strength of the cured film may be determined by controlling parameters of the B-stageable film, such as the depth of the BLT and/or the number and density of void defects. The cure process may be a batch process, or may be performed serially on a continuous basis.

### EXAMPLES

The following examples are intended only to illustrate methods and embodiments in accordance with the invention, and as such should not be construed as imposing limitations upon the claims. Unless specified otherwise, all ingredients are commercially available from such common chemical suppliers as Aldrich Chemical Company (Milwaukee, Wis.), and the like.

A series of B-stageable films are developed for testing in application of a B-stageable film to a heat transfer surface, followed by B-staging, assembly to a complimentary second heat transfer surface, and cure. A heat transfer surface may be a surface of, for example, a substrate of aluminum or copper. Test vehicles (coupons) may be used to simulate assemblies.

Test Methods.

Thermal performance testing may include testing of thermal diffusivity, thermal conductivity, and thermal resistance.

In-situ thermal diffusivity of a coupon is measured by a laser flash method based on ASTM E-1461. A laser flash instrument (MICROFLASH™ 300, purchased from Netzsch Instruments) is used for the measurement. Testing is performed at 25 degrees Celsius. For selected test vehicles, a graphite coating of about 5 microns in thickness is applied as a dispersion of graphite in FLURON® (trademark owned by AP Parts Corporation, Toledo, Ohio). FLURON is a halogenated hydrocarbon liquid carrier for the dispersion of solid lubricants. The graphite coating is applied on the surface of the silicon and the substrate (aluminum or copper) after the cure and prior to testing. The graphite is micron-sized, fine, pure, colloidal synthetic graphite purchased under the trade name DGF 123 dry graphite film lubricant from Miracle Power Products Corporation (Cleveland, Ohio). The graphite is applied in order to enhance absorption of the laser energy and the emission of the infra-red (IR) radiation to the detector.

In-situ thermal conductivity and the lump-sum thermal resistance of the B-staged film are calculated by the measured thermal diffusivity, the physical properties, and associated dimensions of the tri-laminate test coupons. A target thermal resistance may be less than about 300 mm² ° K/W.

Additionally, a shear test, utilizing a Dage model 22 microtester with a 20 kg load cell, is employed to determine mechanical adhesion. The shear test may be a destructive test, and thus, samples that are tested are destroyed by the test. More specifically, samples are prepared by applying B-stageable film onto respective silicon dies (4 mm×4 mm), followed by assembly and cure onto solder mask covered substrates (aluminum or copper). Gripping fixtures of the Dage microtester secure each substrate in place. The shear anvil on the Dage microtester is positioned against the edge of the silicon die with the help of a microscope, and a uniform force is applied to move the shear anvil with tight control in the x, y, and z directions. The uniform force is applied until the silicon die either fractured or separated from the substrate. The load that is required to shear the silicon die off the substrate divided by the shear area yielded the die shear strength in pounds per square inch (psi). A target shear strength for the invention may be greater than about 5000 psi.

The voids percentage at the B-stageable film interface and the bond-line-thickness (BLT) of the B-stageable film, are measured. The voids percentage at the B-stageable film interface is measured with scanning acoustic microscopy (CSAM).

The bond line thickness (BLT) is measured by measuring the thickness of each component layer during assembly.

Furthermore, an air-to-air thermal shock test is performed as an accelerated reliability test to evaluate the performance of coupon. A target COE difference may be less than about 18 ppm/degrees Celsius. A difference larger than 2018 ppm/degrees Celsius in thermal expansion may cause delamination or debonding from a mating surface. Delamination may result in a significant increase in thermal impedance across an interface. The thermal shock test is performed by subjecting samples to temperature cycles from 0 degrees Celsius to 100 degrees Celsius at 10 minutes/cycle. The accelerated thermal shock test is from −50 degrees Celsius to 150 degrees at 10 minutes/cycle. For the accelerated thermal shock test, a target for the number of cycles (from about −50 degrees Celsius to 150 degrees Celsius) until failure of adhesion for cured film may be greater than or equal to about 500 cycles.

Epoxy cresol novolak is commercially available from Sumitomo Chemical Company Limited (Tokyo, Japan). Phenol novolak is commercially available as TAMANOL 758 from Arakawa Chemical. Bisphenol-A-epoxy is commercially available as EPON 826 from Resolution Performance Products (Pueblo, Colo.). The solvent is 1-methoxy-2-propanol (MeOPrOH), commercially available from Alpha Aesar, Inc. (Ward Hill, Mass.) and Aldrich Chemical Company (Milwaukee, Wis.). The catalyst is N-methylimidazole, purchased from Aldrich. Flexibilizer, where used, is polyglycol diepoxide, commercially available as DER 732 from Dow Chemical Company (Midland, Mich.).

One particulate filler is fused silica, commercially available under the trade name LE 10 from JCI USA Inc. (White Plaines, N.Y.). JCI may be the United States distributor for Nippon Chemical Industrial (Tokyo, Japan). Another particulate filler is aluminum, commercially available under the trade name Al 104 from Atlantic Equipment Engineer (Bergenfield, N.J.). Another particulate filler is alumina, commercially available purchased under the trade name DA W05 from (Denka Corporation, New York).

### Example A

Test vehicles are built from aluminum, a B-stageable film, and silicon wafers.

The B-stageable film (prior to the addition of a catalsyt) includes amounts of the ingredients summarized in Table 1A.

TABLE 1A
Composition of Material-A as Master Batch for
B-stageable film (no filler)

| Component | Weight (g) | Weight (%) |
|---|---|---|
| ECN (epoxy cresol novolak) | 40 | 33.97 |
| TAMANOL (phenol novolak, hardener) | 23.04 | 19.57 |
| EPON 826 (bisphenol-A epoxy) | 33 | 28.03 |
| MeOPrOH (1-methoxy-2-propanol, solvent) | 21.7 | 18.43 |
| Total | 117.74 | 100.00 |

The B-stageable film has 0.118 grams of a catalyst added. The catalyst includes N-methylimidazole. The physical properties of a B-staged film formed therefrom are summarized in Table 1B.

TABLE 1B
Physical Properties of Material-A as Master Batch for
B-staged film (no filler)

| | |
|---|---|
| Cured Tg | 150 degrees Celsius to 160 |
| | degrees Celsius |
| Coefficient of Thermal Expansion | 70 ppm/degrees Celsius |

The respective thicknesses of the silicon wafers and of the aluminum for each test vehicle are measured individually before assembly. The properties of the aluminum and of the silicon wafers are summarized below in Table 2.

TABLE 2
Physical Properties of Al and Si in Test Vehicles

| | | | Specific Heat | Thermal Diffusivity |
|---|---|---|---|---|
| | | Density | Capacity | (cm²/second) at 25 |
| Material | Finish | (g/cc) | (J/g ° K) | degrees Celsius |
| Aluminum | Bare | 2.63 | 0.861 | 0.57420 |
| Silicon | Bare wafer | 2.33 | 0.700 | 0.82448 |

The test vehicles are built as follows. The B-stageable film is screen-printed with a stencil onto a heat transfer surface of an aluminum substrate. The stencil has a thickness of 3 mils. The aluminum substrate, with B-stageable film thereon, is B-staged at about 95 degrees Celsius for about 120 minutes under a vacuum of about 100 Torr. The B-staged film is solvent free, tack-free, and solid.

The B-staged film is aligned or registered with a complimentary heat transfer surface of a silicon wafer. The aligned B-staged film is contacted to the silicon wafer heat transfer surface to form an assembly. The assembly is heated to about 150 degrees Celsius for about 60 minutes at about under ambient pressure. Prior to cure, the application of heat softens the B-staged film to allow the B-staged film to flow and to wet the silicon wafer heat transfer surface, and optionally encapsulate the chip by flowing around an edge and into the area under the wafer. The reactive monomers in the B-staged film cross-link in response to the heat. The process is repeated form a plurality of test vehicle assemblies. A pressure load is applied to some of the assemblies during cure to control the bond line thickness. The assemblies are cooled to ambient conditions.

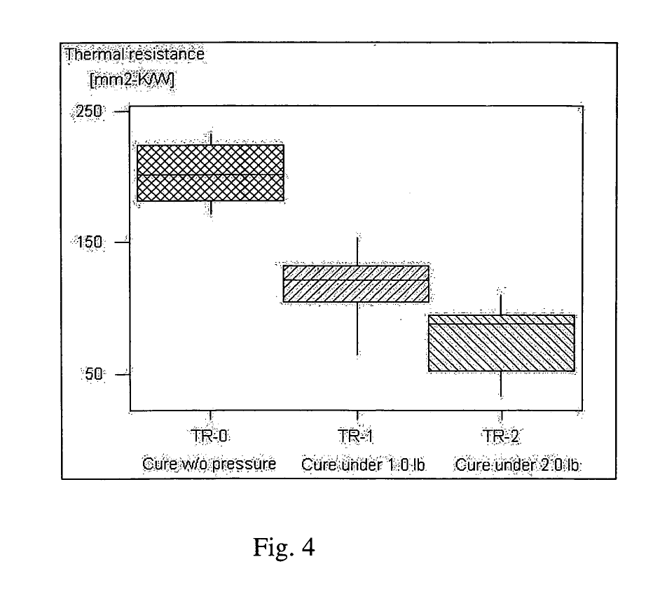

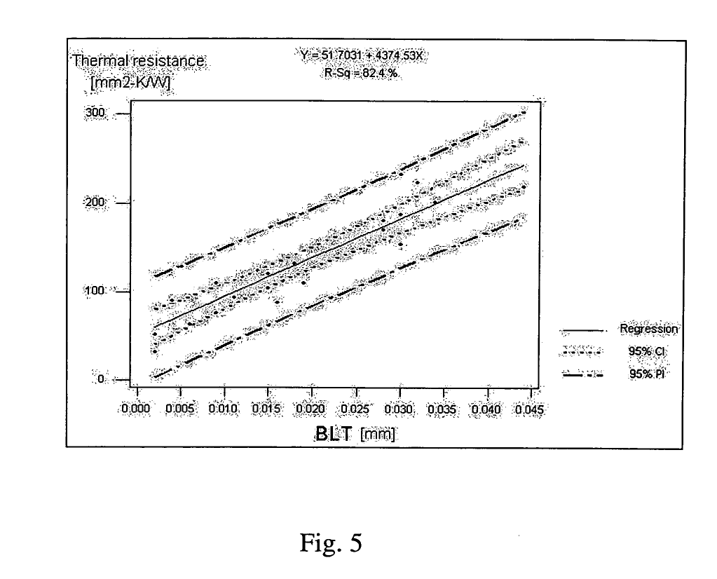

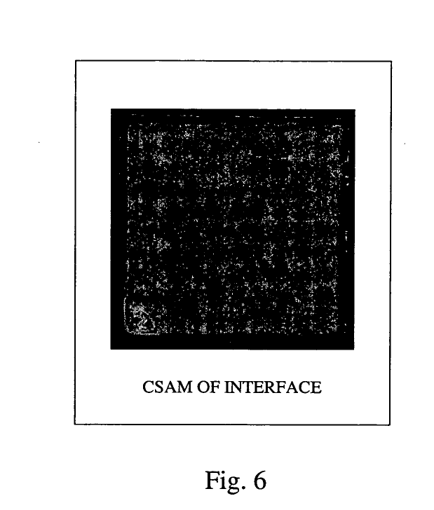

Thermal diffusivity, thermal conductivity, and thermal resistance of the assemblies are measured and the results are listed in Tables 3-8. Particularly, Tables 3 and 4 relate to thermal resistance and thermal conductivity, respectively. Table 5-8 relate to thermal performance for a total 21 samples (Table 5: 7 samples cured without a pressure load, Table 6: 7 samples cured with a pressure load of 1 pound, and Table 7: 7 samples cured with a pressure load of 2 pounds). Also, the thermal resistances at differing pressure loads during cure are depicted in the graph of FIG. 4, and the thermal resistance versus BLT is shown in the graph of FIG. 5. Void percentages at the thermal interface material interface for all 21 samples from each of Tables 5, 6, and 7 are obtained by scanning acoustic microscopy (CSAM). The results are listed in Table 8. A photograph of an exemplary CSAM scan is shown in FIG. 6.

The regression model for thermal resistance is obtained as follows:

The regression equation: y = 51.7 + 4375x

| Predictor | Coefficient | Standard Deviation | T | P |
|---|---|---|---|---|
| Constant | 51.70 | 10.19 | 5.08 | 0.000 |
| x | 4374.5 | 463.5 | 9.44 | 0.000 |

where S = 25.43 R − Sq = 82.4% R − Sq(adj) = 81.5%

Analysis of Variance

| Source | DF | SS | MS | F | P |
|---|---|---|---|---|---|
| Regression | 1 | 57623 | 57623 | 89.07 | 0.000 |
| Residual Error | 19 | 12291 | 647 | | |
| Total | 20 | 69914 | | | |

TABLE 3
Thermal Resistance Summary (no filler)

| Pressure | | | | | | |
|---|---|---|---|---|---|---|
| load | | | | | | |
| during | BLT (mm) | | | Thermal resistance | | |
| cure | Maxi- | Av- | | (mm² ° K/W) | | |
| (pounds) | mum | erage | Minimum | Maximum | Average | Minimum |
| 0.0 | 0.044 | 0.032 | 0.028 | 233.6 | 202.9 | 170.6 |
| 1.0 | 0.030 | 0.015 | 0.005 | 154.0 | 116.3 | 63.701 |
| 2.0 | 0.016 | 0.008 | 0.002 | 109.9 | 77.79 | 32.30 |

TABLE 4
Thermal Conductivity Summary (no filler)

| Pressure | | | | | | |
|---|---|---|---|---|---|---|
| load | | | | | | |
| during | BLT(mm) | | | Thermal conductivity | | |
| cure | Maxi- | Av- | | (W/m ° K) | | |
| (pounds) | mum | erage | Minimum | Maximum | Average | Minimum |
| 0.0 | 0.044 | 0.032 | 0.028 | 0.201 | 0.160 | 0.128 |
| 1.0 | 0.030 | 0.015 | 0.005 | 0.195 | 0.129 | 0.039 |
| 2.0 | 0.016 | 0.008 | 0.002 | 0.182 | 0.092 | 0.038 |

TABLE 5
Thermal Performance (cured without pressure load)

| | Coupon | | | | | | |
|---|---|---|---|---|---|---|---|
| | 1 | 2 | 3 | 4 | 5 | 6 | 7 |
| Total Thickness (mm) | 1.401 | 1.388 | 1.380 | 1.379 | 1.382 | 1.384 | 1.383 |
| Al (mm) | 0.820 | 0.822 | 0.818 | 0.817 | 0.818 | 0.822 | 0.819 |
| BLT (mm) | 0.044 | 0.034 | 0.030 | 0.028 | 0.032 | 0.030 | 0.028 |
| Si (mm) | 0.537 | 0.532 | 0.532 | 0.534 | 0.532 | 0.532 | 0.536 |
| diffusivity 1, 2, 3 | 0.028 | 0.030 | 0.026 | 0.035 | 0.027 | 0.032 | 0.033 |
| (cm²/second) | | | | | | | |
| diffusivity 2 | 0.002 | 0.001 | 0.001 | 0.001 | 0.001 | 0.001 | 0.001 |
| (cm²/second) | | | | | | | |
| conductivity 2 | 0.201 | 0.168 | 0.128 | 0.164 | 0.143 | 0.159 | 0.154 |
| (W/m ° K) | | | | | | | |
| resistance 2 | 218.9 | 202.2 | 233.6 | 170.6 | 224.5 | 188.6 | 181.7 |
| (mm² ° K/W) | | | | | | | |
| conductivity | 6.112 | 6.534 | 5.659 | 7.623 | 5.886 | 6.960 | 7.204 |
| 1, 2, 3 (W/m ° K) | | | | | | | |
| conductivity 1 | 130.0 | 130.0 | 130.0 | 130.0 | 130.0 | 130.0 | 130.0 |
| (W/m ° K) | | | | | | | |
| conductivity 3 | 134.5 | 134.5 | 134.5 | 134.5 | 134.5 | 134.5 | 134.5 |
| (W/m ° K) | | | | | | | |
| resistance 1 | 6.307 | 6.322 | 6.291 | 6.283 | 6.291 | 6.322 | 6.299 |
| (mm² ° K/W) | | | | | | | |
| resistance 3 | 3.993 | 3.956 | 3.956 | 3.971 | 3.956 | 3.956 | 3.986 |
| mm² ° K/W) | | | | | | | |
| resistance total | 229.2 | 212.4 | 243.9 | 180.9 | 234.8 | 198.8 | 192.0 |
| (mm² ° K/W) | | | | | | | |

TABLE 6
Thermal Performance (cured with pressure load of 1 pound)

| | Coupon | | | | | | |
|---|---|---|---|---|---|---|---|
| | 1 | 2 | 3 | 4 | 5 | 6 | 7 |
| Total Thickness (mm) | 1.368 | 1.358 | 1.368 | 1.389 | 1.372 | 1.371 | 1.367 |
| Al (mm) | 0.818 | 0.818 | 0.822 | 0.826 | 0.822 | 0.836 | 0.824 |
| BLT (mm) | 0.019 | 0.006 | 0.015 | 0.030 | 0.018 | 0.005 | 0.015 |
| Si (mm) | 0.531 | 0.534 | 0.531 | 0.533 | 0.532 | 0.530 | 0.528 |
| diffusivity 1, 2, 3 | 0.052 | 0.085 | 0.055 | 0.039 | 0.044 | 0.046 | 0.048 |
| (cm²/second) | | | | | | | |
| diffusivity 2 | 0.001 | 0.001 | 0.001 | 0.002 | 0.001 | 0.000 | 0.001 |
| (cm²/second) | | | | | | | |
| conductivity 2 | 0.172 | 0.094 | 0.144 | 0.195 | 0.136 | 0.039 | 0.124 |
| (W/m ° K) | | | | | | | |
| resistance 2 | 110.2 | 63.71 | 104.3 | 154.0 | 132.2 | 128.6 | 120.8 |
| (mm² ° K/W) | | | | | | | |
| conductivity | 11.36 | 18.36 | 11.94 | 8.541 | 9.625 | 9.861 | 10.43 |
| 1, 2, 3 (W/m ° K) | | | | | | | |
| conductivity 1 | 130.0 | 130.0 | 130.0 | 130.0 | 130.0 | 130.0 | 130.0 |
| (W/m ° K) | | | | | | | |
| conductivity 3 | 134.5 | 134.5 | 134.5 | 134.5 | 134.5 | 134.5 | 134.5 |
| (W/m ° K) | | | | | | | |
| resistance 1 | 6.291 | 6.291 | 6.322 | 6.353 | 6.322 | 6.430 | 6.337 |
| (mm² ° K/W) | | | | | | | |
| resistance 3 | 3.949 | 3.971 | 3.949 | 3.964 | 3.956 | 3.941 | 3.926 |
| (mm² ° K/W) | | | | | | | |
| resistance total | 120.4 | 73.97 | 114.6 | 164.3 | 142.5 | 139.0 | 131.1 |
| (mm² ° K/W) | | | | | | | |

TABLE 7
Thermal Performance (cured with pressure load of 2 pounds)

| | Coupon | | | | | | |
|---|---|---|---|---|---|---|---|
| | 1 | 2 | 3 | 4 | 5 | 6 | 7 |
| Total Thickness (mm) | 1.363 | 1.355 | 1.359 | 1.358 | 1.366 | 1.354 | 1.359 |
| Al (mm) | 0.820 | 0.820 | 0.818 | 0.819 | 0.818 | 0.820 | 0.822 |
| BLT (mm) | 0.011 | 0.002 | 0.009 | 0.016 | 0.016 | 0.002 | 0.004 |
| Si (mm) | 0.532 | 0.533 | 0.532 | 0.530 | 0.532 | 0.532 | 0.533 |
| diffusivity 1, 2, 3 | 0.060 | 0.100 | 0.052 | 0.072 | 0.064 | 0.148 | 0.062 |
| (cm²/second) | | | | | | | |
| diffusivity 2 | 0.001 | 0.000 | 0.001 | 0.001 | 0.001 | 0.000 | 0.000 |
| (cm²/second) | | | | | | | |
| conductivity 2 | 0.117 | 0.038 | 0.082 | 0.117 | 0.182 | 0.062 | 0.044 |
| (W/m ° K) | | | | | | | |
| resistance 2 | 94.30 | 52.39 | 109.9 | 76.92 | 88.04 | 32.30 | 90.68 |
| (mm² ° K/W) | | | | | | | |
| conductivity | 13.04 | 21.63 | 11.31 | 15.58 | 13.90 | 31.81 | 13.46 |
| 1, 2, 3 (W/m ° K) | | | | | | | |
| conductivity 1 | 130.0 | 130.0 | 130.0 | 130.0 | 130.0 | 130.0 | 130.0 |
| (W/m ° K) | | | | | | | |
| conductivity 3 | 134.5 | 134.5 | 134.5 | 134.5 | 134.5 | 134.5 | 134.5 |
| (W/m ° K) | | | | | | | |
| resistance 1 | 6.307 | 6.307 | 6.291 | 6.299 | 6.291 | 6.307 | 6.322 |
| (mm² ° K/W) | | | | | | | |
| resistance 3 | 3.956 | 3.964 | 3.956 | 3.941 | 3.956 | 3.956 | 3.964 |
| (mm² ° K/W) | | | | | | | |
| resistance total | 104.6 | 62.66 | 120.17 | 87.16 | 98.29 | 42.57 | 101.0 |
| (mm² ° K/W) | | | | | | | |

TABLE 8
Void Area % of thermal interface material Interface

| | Pressure load | Pressure load | Pressure load |
|---|---|---|---|
| | during cure - | during cure - | during cure - |
| | 0 pound (samples | 1 pound (samples | 2 pounds (samples |
| Coupon | from Table 5) | from Table 6) | from Table 7) |
| 1 | 3.6% | 2.7% | 3.6% |
| 2 | 1.2% | 9.2% | 8.2% |
| 3 | 13.1% | 14.8% | 17.5% |
| 4 | 1.5% | 38.5% | 1.3% |
| 5 | 7.2% | 0.8% | 2.9% |
| 6 | 13.5% | 3.4% | 1.9% |
| 7 | 4.3% | 6.9% | 0.0% |
| Maximum | 13.5% | 38.5% | 17.5% |
| Average | 6.4% | 10.9% | 5.0% |
| Minimum | 1.2% | 0.8% | 0.0% |

The regression equation: TR = 52.7 + 4402 BLT − 0.203 Void

| Predictor | Coefficient | Standard Deviation | T | P |
|---|---|---|---|---|
| Constant | 52.70 | 10.96 | 4.81 | 0.000 |
| BLT | 4402.3 | 484.0 | 9.10 | 0.000 |
| Void | −0.2029 | 0.6779 | −.030 | 0.768 |

where S = 26.07 R − Sq = 82.5% R − Sq(adj) = 80.6%

Analysis of Variance

| Source | DF | SS | MS | F | P |
|---|---|---|---|---|---|
| Regression | 2 | 57684 | 28842 | 42.45 | 0.000 |
| Residual Error | 18 | 12230 | 679 | | |
| Total | 20 | 69914 | | | |

Thermal resistance increases about linearly with the BLT. The test vehicles cured under a pressure load had less area void percentage (median) than those cured without a pressure load. From the regression analysis, controlling the BLT allows for control over void percentage and thermal resistance.

A DAGE MODEL 22 microtester with a 20 kilogram (kg) load cell is employed to determine mechanical adhesion via shear test. Twelve separate samples of unfilled B-staged film are prepared by applying a B-stageable material onto a heat transfer surface of respective silicon dies. The B-stageable material is B-staged. The B-staged films are aligned and contacted to respective solder mask covered aluminum substrates. The B-staged film is cured. The cured film is tested. From the shear test, the average adhesive or shear strength is about 2500 pounds per square inch (psi). The shear test results are summarized below in Table 9.

TABLE 9
Shear Test Results of thermal interface material (Material-A
with catalyst - no filler)

| | Diameter | Diameter | Area | | |
|---|---|---|---|---|---|
| Sample | (micrometers) | (inches) | (square inches) | pounds | psi |
| 1 | 1300 | 0.0512 | 0.00205944 | 6.8 | 3301.87 |
| 2 | 1375 | 0.0542 | 0.00230392 | 0.6 | 260.43 |
| 3 | 1800 | 0.0709 | 0.00394827 | 6.7 | 1696.94 |
| 4 | 1709 | 0.0673 | 0.00355915 | 10.6 | 2978.24 |
| 5 | 1319 | 0.0520 | 0.00212008 | 5.2 | 2452.74 |
| 6 | 1359 | 0.0535 | 0.00225061 | 5.9 | 2621.51 |
| 7 | 1484 | 0.0585 | 0.00268367 | 6.7 | 2496.58 |
| 8 | 1925 | 0.0758 | 0.00451568 | 11.9 | 2635.26 |
| 9 | 1320 | 0.0520 | 0.00212329 | 2.1 | 989.03 |
| 10 | 1128 | 0.0444 | 0.00155053 | 5 | 3224.70 |
| 11 | 1494 | 0.0589 | 0.00271996 | 9.6 | 3529.46 |
| 12 | 1278 | 0.0504 | 0.00199032 | 6.6 | 3316.04 |

Reliability characterization is determined by performing an accelerated thermal shock test (−50 to 150 degrees Celsius) on test vehicles. All test vehicles passed 500 hours thermal shock testing, and achieved a rating of thermomechanical reliability. The process conditions and reliability performances for each of the 7 samples respectively from each of Tables 5, 6, and 7 are summarized below in Table 10.

TABLE 10
Thermal Shock Test Results (no filler)

| | | | | Post 500 |
|---|---|---|---|---|
| | Test | Application | Pressure | hour |
| Samples | Conditions | method | (psi) | failure |
| 7 samples | −50 degrees Celsius to | Screen print | 0 | 0 |
| from Table 5 | 150 degrees Celsius, | with stencil | | |
| | 10 minutes dwelling | | | |
| 7 samples | −50 degrees Celsius to | Screen print | 10 | 0 |
| from Table 6 | 150 degrees Celsius, | with stencil | | |
| | 10 minutes dwelling | | | |
| 7 samples | −50 degrees Celsius to | Screen print | 20 | 0 |
| from Table 7 | 150 degrees Celsius, | with stencil | | |
| | 10 minutes dwelling | | | |

### Example B

Filled B-stageable film Samples B1, B2, B3, and B4 are prepared as follows. The differences among film Samples B1, B2, B3, and B4 are that B1 includes silica, B2 includes aluminum, B3 and B4 include differing alumina.

The amount of filler added is 2 weight percent of silica, 70 weight percent of aluminum, and 70 weight percent of alumina, based on the total weight of the composition. The amount of catalyst added is 0.1 weight percent, based on the total weight of the composition. Also, for Sample B4, a portion of the resin is replaced with a flexibilizer. The amounts of the various ingredients of the thermal interface material may be summarized below in Tables 11, 12, 13, and 14.

TABLE 11
Sample B1

| Component | Function | Weight (g) |
|---|---|---|
| ECN (epoxy cresol novolak) | resin | 40 |
| TAMANOL (phenol novolak) | hardener | 23.04 |
| EPON 826 (bisphenol-A epoxy) | resin | 33 |
| MeOPrOH (1-methoxy-2-propanol) | solvent | 21.7 |
| NMI (N-methylimidazole) | catalyst | 0.118 |
| LE 10 (fused silica) | filler | 2.35 |
| Total | — | 120.21 |

TABLE 12
Sample B2

| Component | Function | Weight (g) |
|---|---|---|
| ECN (epoxy cresol novolak) | resin | 40 |
| TAMANOL (phenol novolak) | hardener | 23.04 |
| EPON 826 (bisphenol-A epoxy) | resin | 33 |
| MeOPrOH (1-methoxy-2-propanol) | solvent | 21.7 |
| NMI (N-methylimidazole) | catalyst | 0.118 |
| Al 104 (aluminum) | filler | 82.42 |
| Total | — | 200.28 |

TABLE 13
Sample B3

| Component | Function | Weight (g) |
|---|---|---|
| ECN (epoxy cresol novolak) | resin | 40 |
| TAMANOL (phenol novolak) | hardener | 23.04 |
| EPON 826 (bisphenol-A epoxy) | resin | 33 |
| MeOPrOH (1-methoxy-2-propanol) | solvent | 21.7 |
| NMI (N-methylimidazole) | catalyst | 0.118 |
| DA W05 (alumina) | filler | 82.42 |
| Total | — | 200.28 |

TABLE 14
Sample B4

| Component | Function | Weight (g) |
|---|---|---|
| ECN (epoxy cresol novolak) | resin | 32 |
| DER 732 (polyglycol di-epoxide) | flexibilizer | 8 |
| TAMANOL (phenol novolak) | hardener | 23.04 |
| EPON 826 (bisphenol-A epoxy) | resin | 33 |
| MeOPrOH (1-methoxy-2-propanol) | solvent | 21.7 |
| NMI (N-methylimidazole) | catalyst | 0.118 |
| DA 105 (alumina) | filler | 82.42 |
| Total | — | 200.28 |

The silicon is a 8 mm×8 mm flip chip device. Particularly, a silicon device is assembled onto a high glass transition temperature FR-4 laminate (flame retardant, type 4 laminate), where assembly onto copper pads on the laminate is accomplished using a no-clean tacky flux and a tin-lead reflow profile. FR-4 laminate may be a base material from which plated printed circuit boards may be constructed. FR-4 laminate is a woven glass reinforced epoxy resin constructed from glass fabric impregnated with epoxy resin and copper foil. Solder interconnections (2 mils in height) interconnect the silicon device to the laminate. The flip chip device has standard eutectic tin-lead (63 Sn/37 Pb) solder bumps (4 mils in height), 88 I/Os (Input/Output), and a pitch of 8 mils. The passivation layer on the device is silicon nitride. The substrate is copper having a 8 mm×8 mm heat spreader with a matte nickel finish.

Each of Samples B1-B4 is printed onto a heat transfer surface of each copper heat spreader in a full and continuous dispense pattern, using a screen printer and stencil in a manner similar to Example 1. The volume of material needed for the B-stageable film is calculated based on the area covered and the desired thickness (BLT), and accounts for the loss in solvent volume during the B-stage process. For Samples B1-B4 a 1 mil thickness of B-stageable material is printed onto each copper heat spreader.

The resultant copper heat spreader with the B-stageable film is B-staged in a vacuum oven at 95 degrees Celsius for 1.5 hours at full vacuum—less than 10 mm of Hg (10 Torr). A solid B-staged film, which retains the shape in which it is dispensed, is obtained on each copper heat spreader.

Each copper heat spreader with the B-staged film is aligned with the backside of a silicon flip chip. The exposed surface of the B-staged film is contacted to a heat transfer surface of the chip to form an assembly. A metallic clip, which exerts 1 pound of force, is applied to hold together each assembly of copper/B-stageable material/silicon.

During cure, each assembly is placed in an isothermal oven at 150 degrees Celsius for 40 minutes. As the temperature ramps up the B-staged film softens and flows to wet the silicon flip chip heat transfer surface. At 150 degrees Celsius, the B-staged film cures. The cured assembly cools to ambient conditions, and fillet formation is observed on 4 sides of the chip and at the corners.

Each of the copper spreader and the silicon flip chip are measured at 5 different locations prior to assembly, and the average of each set of 5 measurements is calculated. The total thickness of the assembly is measured. The bond-line-thickness (BLT) is determined by subtracting the components thickness from total thickness of the assembly.

The coefficient of thermal expansion and the glass transition temperature (cured Tg) are measured. The cured assemblies are coated with a thin layer of graphite prior to conducting thermal performance testing. The samples are subjected to adhesion testing with standard deviation, denoted as SD. The results of the measurements and tests for each of Samples B1, B2, B3, and B4, are summarized below in Table 15.

TABLE 15
Results of thermal performance testing.

| | B1 (from | B2 (from | B3 (from | B4 (from |
|---|---|---|---|---|
| Test or Measurement | Table 11) | Table 12) | Table 13) | Table 14) |
| BLT | 18 | 22.3 | 47 | 47 |
| (micrometers) | (SD ˜2.9) | (SD ˜1) | (SD ˜4.5) | (SD ˜6) |
| Coefficient of Thermal | 61 | 60 | 38 | Not tested |
| Expansion | | | | |
| (ppm/degrees Celsius) | | | | |
| Cured Tg | 163 | 128 | 107 | Not |
| (degrees Celsius) | | | | tested |
| Shear Test - Adhesion (psi) | 5400 | 7900 | 6850 | Not |
| | (SD ˜2200) | (SD ˜950) | (SD ˜1850) | tested |
| Thermal Resistance (mm² ° K/W) | 85 | 25 | 56 | 63 |
| Accelerated Thermal Shock | 750 | Not tested | Not tested | 500 |
| (number of cycles, from −50 | | | | |
| degrees Celsius to 150 | | | | |
| degrees Celsius, until failure) | | | | |

The foregoing examples are merely illustrative, serving to illustrate only some of the features of the invention. The appended claims are intended to claim the invention as broadly as it has been conceived and the examples herein presented are illustrative of selected embodiments from a manifold of all possible embodiments. Accordingly it is Applicants' intention that the appended claims are not to be limited by the choice of examples utilized to illustrate features of the present invention. As used in the claims, the word “comprises” and its grammatical variants logically also subtend and include phrases of varying and differing extent such as for example, but not limited thereto, “consisting essentially of” and “consisting of.” Where necessary, ranges have been supplied, those ranges are inclusive of all sub-ranges there between. It is to be expected that variations in these ranges will suggest themselves to a practitioner having ordinary skill in the art and where not already dedicated to the public, those variations should where possible be construed to be covered by the appended claims. It is also anticipated that advances in science and technology will make equivalents and substitutions possible that are not now contemplated by reason of the imprecision of language and these variations should also be construed where possible to be covered by the appended claims.

What is claimed is:

1. A film comprising a thermal interface material that is operable to be disposed on a heat transfer surface to secure a heat-generating device to a heat-dissipating component, the film is further operable to flow, to cross-link, and to conduct thermal energy from the heat-generating device to the heat-dissipating component.

2. The film as defined in claim 1, wherein one or both of the heat-generating device or the heat-dissipating component comprises metal.

3. The film as defined in claim 2, wherein the metal comprises one or both of copper or aluminum.

4. The film as defined in claim 1, wherein the film has less than about 50 percent of the reactive monomers cross-linked.

5. The film as defined in claim 1, wherein the film further comprises one or more epoxy resin, acrylate resin, organo-functionalized polysiloxane resin, polyimide resin, fluorocarbon resin, benzocyclobutene resin, fluorinated polyallyl ether resin, polyamide resin, polyimidoamide resin, phenol cresol resin, aromatic polyester resin, polyphenylene ether resin, bismaleimide triazine resin, or fluororesin.

6. The film as defined in claim 5, wherein the epoxy resin comprises one or more cresol-novolak epoxy resin, bisphenol-A epoxy resin, bisphenol-F epoxy resin, phenol novolak epoxy resin, bisphenol epoxy resin, biphenyl epoxy resin, 4,4′-biphenyl epoxy resin, polyfunctional epoxy resin, divinylbenzene dioxide, and 2-glycidylphenylglycidyl ether, triglycidyl isocyanurate epoxy, butadiene dioxide, dimethylpentane dioxide, resorcinol diglycidyl ether, polyglycol di-epoxide, 1,4-butane dioldiglycidyl ether, diethylene glycol diglycidyl ether, or dipentene dioxide.

7. The film as defined in claim 5, wherein the resin is present in an amount in a range of from about 1 weight percent to about 70 weight percent based on the total weight of the film.

8. The film as defined in claim 1, wherein the film further comprising a hardener.

9. The film as defined in claim 7, wherein the hardener comprises one or more amine epoxy hardener, phenolic resin hardener, carboxylic acid-anhydride hardener, or novolak hardener.

10. The film as defined in claim 7, wherein the hardener is present in an amount in a range of from about 1 weight percent to about 25 weight percent based on the total weight of the film.

11. The film as defined in claim 1, wherein the film further comprises one or both of a curing agent or a cure catalyst.

12. The film as defined in claim 10, wherein the curing agent comprises one or more azo compound, organic peroxide, or anhydride compound.

13. The film as defined in claim 10, wherein the curing agent is present in an amount in a range of from about 1 weight percent to about 25 weight percent based on the total weight of the film.

14. The film as defined in claim 10, wherein the cure catalyst comprises one or more amine, imidazole, imidazolium salt, phosphine, metal salt, or a salt of a nitrogen-containing compound.

15. The method as defined in claim 10, wherein the cure catalyst is present in an amount in a range of from about 1 weight percent to about 25 weight percent based on the total weight of the film.

16. The film as defined in claim 1, wherein the thermal interface material comprises a thermally conductive metal having a softening point in a range that is less than a cure temperature of the film.

17. The film as defined in claim 1, wherein the thermal interface material comprises a particulate filler.

18. The film as defined in claim 16, wherein the filler comprises one or more of alumina, boron nitride, silica, talc, or zinc oxide; or a metal comprising aluminum, boron, gallium, indium, phosphorus, tin, or alloys or mixtures of two or more thereof.

19. The film as defined in claim 16, wherein the filler comprises nanoscale particles that were pretreated with one or both of a compatiblizing agent or a passivating agent.

20. The film as defined in claim 16, wherein the filler is present in an amount in a range of from about 1 weight percent to about 95 weight percent based on the total weight of the film.

21. The film as defined in claim 1, further comprising an organic solvent comprises one or more of 1-methoxy-2-propanol, methoxy propanol acetate, butyl acetate, methoxyethyl ether, methanol, ethanol, isopropanol, ethyleneglycol, ethylcellosolve, methylethyl ketone, cyclohexanone, benzene, toluene, xylene, ethyl acetate, cellosolve acetate, butyl cellosolve acetate, carbitol acetate, or butyl carbitol acetate.

22. The film as defined in claim 20, wherein the solvent is present in an amount in a range of from about 1 weight percent to about 95 weight percent based on the total weight of the film.

23. A B-staged curable- film formed from the B-stageable film defined in claim 1.

24. The B-staged curable film as defined in claim 22, which is essentially solvent-free.

25. The B-staged curable film as defined in claim 22, which is at least partially cross-linked or solidified.

26. The B-staged curable film as defined in claim 22, wherein the film is a discontinuous layer.

27. The B-staged curable film as defined in claim 22, wherein the film comprises at least one portion having one or more of a thermal resistance, an electrical conductivity, a bond line thickness, a shear strength, a flexibility, or an adhesive strength that differs from a corresponding thermal resistance, electrical conductivity, bond line thickness, shear strength, flexibility, or adhesive strength of another portion of the film.

28. The B-staged curable film as defined in claim 22, wherein the film comprises at least one portion having one or more of a thermal resistance, an electrical conductivity, a bond line thickness, a shear strength, a flexibility, or an adhesive strength that differs from a corresponding a thermal resistance, an electrical conductivity, a bond line thickness, a shear strength, a flexibility, or an adhesive strength in another portion of the film.

29. The B-staged curable film as defined in claim 22, wherein the film has a bond line thickness in a range of greater than about 5 micrometers.

30. The B-staged curable film as defined in claim 22, wherein the film is one or more of solid, tack-free, or hard at about room temperature.

31. The B-staged curable film as defined in claim 22, wherein the film is operable to soften, flow, or soften and flow at a temperature that is greater than room temperature but below a cure temperature of the film.

32. An electronic assembly, comprising:
an heat-generating device;
a heat-dissipating component; and
the film as defined in claim 22 securing the heat-dissipating component to the heat-generating device.

33. The electronic assembly as defined in claim 31, wherein the film has properties comprising one or more of:
a shear strength that is greater than about 5000 psi,
a thermal resistance that is less than about 300 mm² ° K/W, or
a bond line thickness that is in a range of from about 10 micrometers to about 70 micrometers.

34. The electronic assembly as defined in claim 31, wherein the heat-generating device comprises one or more of an integrated chip, a power chip, power source, light source, motor, sensor, capacitor, fuel storage compartment, conductor, inductor, switch, diode, or transistor.

35. The electronic assembly as defined in claim 31, wherein the heat-dissipating component comprises one or more of a heat sink, heat radiator, heat spreader, heat pipe, or Peltier heat pump.

36. A method of making an electronic device, comprising:
B-staging a film on a heat transfer surface of one of a heat-generating device or a heat-dissipating device so that the B-staged film has an inward-facing surface in contact with at least a portion of the heat transfer surface and an outward-facing surface that is initially exposed, the film being operable to further cross-link, and to conduct thermal energy;
contacting the exposed film surface to the surface of the other of the heat-generating device or the heat-dissipating device to form a sandwich structure; and
curing the B-staged film.

37. The method as defined in claim 35, wherein B-staging the film comprises evaporating solvent.

38. The method as defined in claim 35, wherein B-staging the film comprises completing cross-linking of reactive monomers that comprise at least a portion of the B-staged film.

39. The method as defined in claim 37, wherein completing cross-linking comprises applying one or more of heat, electron beam, or ultraviolet light to the reactive monomers.

40. The method as defined in claim 35, wherein B-staging the film comprises applying a negative pressure to the film that is in a range of from about 10 Torr to about 250 Torr.

41. The method as defined in claim 35, further comprising aligning the exposed film surface to the surface of the other of the heat-generating device or the heat-dissipating device.

42. The method as defined in claim 35, wherein B-staging the film comprises heating the film to a temperature in a range of greater than about 50 degrees Celsius followed by cooling the film to an ambient temperature before achieving a complete cure of the B-staged film.

43. The method as defined in claim 41, wherein B-staging the film is performed at a temperature that is lower than a melting temperature of solder balls embedded in the B-staged film.

44. The method as defined in claim 42, further comprising curing the B-staged film simultaneously with melting the solder balls to both cure the B-staged film and form electrical contacts using the solder balls.

45. The method as defined in claim 35, wherein forming the B-staged film comprises screen-printing the B-staged film onto a predetermine area of a heat transfer surface, or flowing the B-staged film through an aperture, a groove, or a center cut line and onto the heat transfer surface.

46. The method as defined in claim 35, further comprising one or more of stacking, storing, or handling the B-staged film prior to curing the B-staged film.
